(19) United States
(12) Patent Application Publication
(10) Pub. No.: US 2021/0272877 A1
(43) Pub. Date: Sep. 2, 2021

(54) SEMICONDUCTOR DEVICE INCLUDING HETEROJUNCTION BIPOLAR TRANSISTOR

(71) Applicant: Advanced Wireless Semiconductor Company, Tainan City (TW)

(72) Inventors: You-Min CHI, Tainan City (TW); Kuo-Chun HUANG, Tainan City (TW); Kun-Mu HSIEH, Tainan City (TW); Yu-Chen CHIU, Tainan City (TW); Chi-Chun LIN, Tainan City (TW); Wen-Pin LU, Tainan City (TW); Chao-Hung CHEN, Tainan City (TW)

(21) Appl. No.: 17/025,958

(22) Filed: Sep. 18, 2020

(30) Foreign Application Priority Data
Mar. 2, 2020 (TW) 109202306

(51) Int. Cl. H01L 23/42; H01L 27/102; H01L 29/737; H01L 23/485

(52) U.S. Cl. CPC H01L 23/42; H01L 23/485; H01L 29/7371; H01L 27/1024

(57) ABSTRACT

A semiconductor device includes a substrate, at least one heterojunction bipolar transistor including a semiconductor unit and an electrode unit, an insulation unit, and a heat dissipation unit. The insulation unit covers the substrate and the heterojunction bipolar transistor such that a collector electrode, a base electrode and an emitter electrode of the electrode unit are electrically isolated from one another. The insulation unit is formed with an opening to expose an electrode wire of the emitter electrode. The heat dissipation unit covers the electrode wire and is made of an electrically conductive and heat dissipating material, and has a thickness that is not less than 3 μm.

### CROSS-REFERENCE TO RELATED APPLICATION

This application claims priority of Taiwanese Utility Model Patent Application No. 109202306, filed on Mar. 2, 2020.

### FIELD

The present disclosure relates to a semiconductor device, and more particularly to a semiconductor device including a heterojunction bipolar transistor that has a high heat dissipation efficiency.

### BACKGROUND

Referring to FIG. 1, a conventional heterojunction bipolar transistor (HBT) 1 used in a power amplifier includes a substrate 11, a semiconductor unit 12, an electrode unit 13, and an insulating unit 14. The semiconductor unit 12 includes a collector layer 121, a base layer 122 and an emitter layer 123 that are sequentially formed on the substrate 11 in such order. The electrode unit 13 includes a collector electrode 131, a base electrode 132 and an emitter electrode 133 that are respectively disposed on the collector layer 121, the base layer 122 and the emitter layer 123. The insulating unit 14 includes a first insulating layer 141 and a second insulating layer 142 that covers the first insulating layer 141. The first insulating layer 141 covers the substrate 11, the semiconductor unit 12 and the electrode unit 13 for electrically isolating the collector electrode 131, the base electrode 132 and the emitter electrode 133 from one another. The insulating unit 14 is formed with through holes 143 to respectively expose a portion of the collector electrode 131, a portion of the base electrode 132, and a portion of the emitter electrode 133. The electrode unit 13 further includes an electrical wire 134 which extends outwardly from the exposed portion of the emitter electrode 133 through the corresponding through hole 143, so as to electrically connect the conventional HBT 1 to an external power source (not shown in the figure).

In order to meet the requirements for a high-power device (such as a high-speed wireless communication system), active electronic components (such as a power amplifier) should have satisfactory high-frequency characteristics and a high power output, so as to withstand relatively large amounts of current and voltage. In use, a large amount of heat would be generated and accumulated in the high-power device, and thus a high heat dissipation efficiency becomes essential for such high-power device. However, as shown in FIG. 1, although the second insulating layer 142 having a multi-layered structure (or alternatively a single-layer structure) can protect components of the conventional HBT 1, the second insulating layer 142 is generally made of a polymer material or an inorganic material having a poor thermal conductivity, thereby adversely affecting the heat dissipation efficiency of the conventional HBT 1.

### SUMMARY

Therefore, an object of the present disclosure is to provide a semiconductor device having a heterojunction bipolar transistor that can alleviate at least one of the drawbacks of the prior art.

According to the present disclosure, the semiconductor device includes a substrate, at least one heterojunction bipolar transistor, an insulation unit, and a heat dissipation unit.

The heterojunction bipolar transistor includes a semiconductor unit and an electrode unit. The semiconductor unit includes a collector layer, a base layer and an emitter layer that are sequentially formed on the substrate in such order. The electrode unit includes a collector electrode, a base electrode and an emitter electrode that are respectively disposed on the collector layer, the base layer and the emitter layer. The emitter electrode includes an electrode wire that extends in a direction away from the emitter layer. The insulation unit covers the substrate and the heterojunction bipolar transistor such that the collector electrode, the base electrode and the emitter electrode are electrically isolated from one another. The insulation unit is formed with a plurality of openings to respectfully expose the collector electrode, the base electrode and the electrode wire of the emitter electrode. The heat dissipation unit covers the electrode wire of the emitter electrode and is exposed outwardly. The heat dissipation unit is made of an electrically conductive and heat dissipating material, and has a thickness that is not less than 3 μm.

### BRIEF DESCRIPTION OF THE DRAWINGS

Other features and advantages of the present disclosure will become apparent in the following detailed description of the embodiment with reference to the accompanying drawings, of which:

FIG. 1 is a fragmentary schematic view illustrating a conventional heterojunction bipolar transistor;

FIG. 2 is a fragmentary schematic view illustrating an embodiment of a semiconductor device including at least one heterojunction bipolar transistor according to the present disclosure; and

FIG. 3 is a partially enlarged view of the heterojunction bipolar transistor from FIG. 2.

### DETAILED DESCRIPTION

Before the present disclosure is described in greater detail, it should be noted that where considered appropriate, reference numerals or terminal portions of reference numerals have been repeated among the figures to indicate corresponding or analogous elements, which may optionally have similar characteristics.

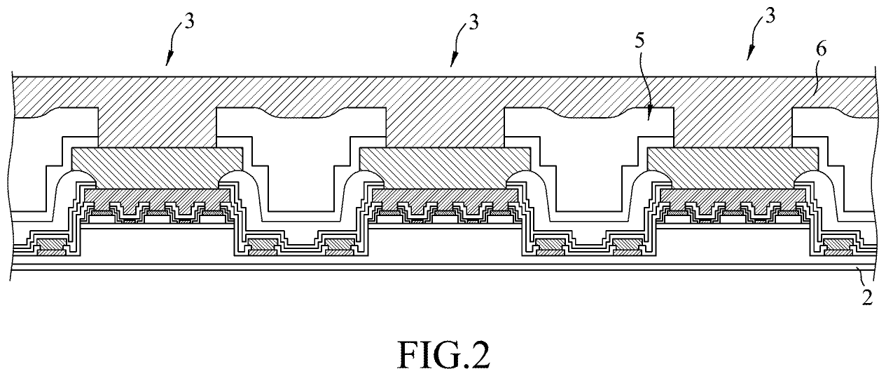

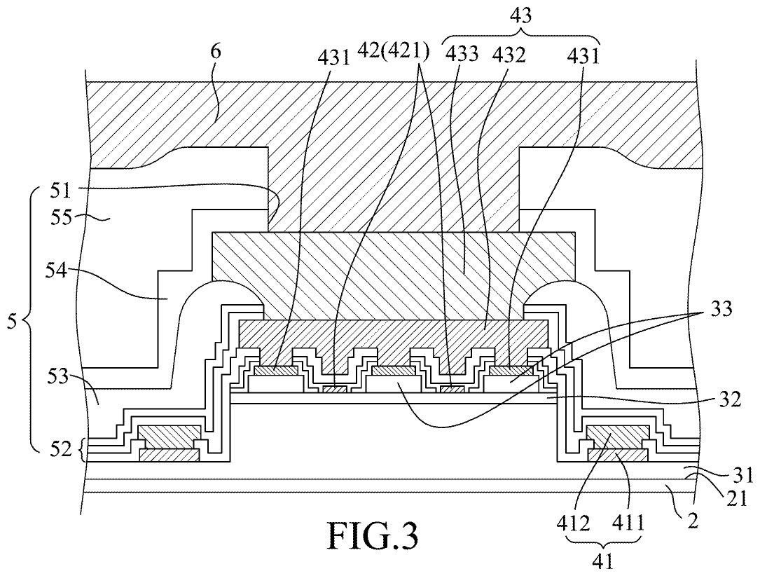

Referring to FIGS. 2 and 3, an embodiment of a semiconductor device according to the present disclosure includes a substrate 2, at least one heterojunction bipolar transistor 3, an insulation unit 5, and a heat dissipation unit 6.

The substrate 2 may be made of a semi-insulating semiconductor material, e.g., gallium arsenide (GaAs) or indium phosphide (InP).

In this embodiment, the semiconductor device includes a plurality of the heterojunction bipolar transistors 3 that are arranged in an array and that are spacedly disposed on the substrate 2. For illustration purpose, three of the heterojunction bipolar transistors 3 are shown in FIG. 2.

Each of the heterojunction bipolar transistors 3 includes a semiconductor unit and an electrode unit.

The semiconductor unit includes a collector layer 31, a base layer 32 and an emitter layer 33 that are sequentially formed on a top surface 21 of the substrate 2 in such order.

Each of the collector layer 31, the base layer 32 and the emitter layer 33 may be made of a group III-V semiconductor material. Examples of the group III-V semiconductor material may include, but are not limited to, gallium nitride (GaN), gallium arsenide (GaAs), indium gallium arsenide (InGaAs), indium phosphide (InP), and indium gallium phosphide (InGaP). The collector layer 31, the base layer 32 and the emitter layer 33 may be independently formed as a single layer structure or a multi-layered structure. Since the material and structure of the collector layer 31, the base layer 32 and the emitter layer 33 are well known to those skilled in the art, further details thereof are not provided herein for the sake of brevity.

The electrode unit includes a collector electrode 41, a base electrode 42 and an emitter electrode 43 that are respectively disposed on the collector layer 31, the base layer 32 and the emitter layer 33. The collector electrode 41 includes a collector electrode layer 411 and a contact electrode pad 412 that are sequentially formed on the collector layer 31 opposite to the substrate 2 in such order. The base electrode 42 includes a base electrode layer 421 that is formed on the base layer 32. The emitter electrode 43 includes an emitter electrode layer 431 and a contact electrode pad 432 that are sequentially formed on the emitter layer 33 opposite to the base layer 32 in such order, and an electrode wire 433 that extends outwardly from the contact electrode pad 432 in a direction away from the emitter layer 33. Each of the collector electrode 41, the base electrode 42 and the emitter electrode 43 may be made of an electrically conductive material (such as metal and metal alloy), and may be formed as a single layer structure or a multi-layered structure. As shown in FIG. 2, each of the collector electrode layer 411, the contact electrode pad 412, the base electrode layer 421, the emitter electrode layer 431, the contact electrode pad 432, and the electrode wire 433 in this embodiment is formed as a single-layer structure, but is not limited thereto in actual practice.

The insulation unit 5 covers the substrate 2 and each heterojunction bipolar transistor 3 such that the collector electrode 41, the base electrode 42 and the emitter electrode 43 are electrically isolated from one another. The insulation unit 5 is formed with a plurality of openings 51 to respectively expose the top surfaces of the following: the collector electrode 41, the base electrode 42, and the electrode wire 433 of the emitter electrode 43. For illustration purpose, only the opening 51 exposing the electrode wire 433 is shown in FIG. 3.

Examples of a material for forming the insulation unit 5 may include an organic insulating material or an inorganic insulating material. The insulation unit 5 may be formed as a multi-layered structure, and the number of the layers in the insulation unit 5 may be varied depending on the manufacturing process. In this embodiment, the insulation unit 5 includes a silicon nitride multi-layered structure 52 that covers the exposed surfaces of the following: each component of the semiconductor unit, a portion of the collector electrode 41, a portion of the base electrode 42, and a portion of the emitter electrode 43. The insulation unit 5 further includes a polyimide layer 53 that is formed on the silicon nitride multi-layered structure 52, a silicon nitride layer 54 that covers the polyimide layer 53 and that extends to cover a portion of the electrode wire 433, and a polyolefin layer 55 that covers the silicon nitride layer 54. In addition, by controlling the thickness of the insulation unit 5 (such as the thickness of the polyolefin layer 55), a height difference between each component of the heterojunction bipolar transistor 3 may be reduced.

The heat dissipation unit 6 is connected to and covers the electrode wire 433 of the emitter electrode 43 by extending through the corresponding opening 51, and is exposed outwardly. The heat dissipation unit 6 may further extend to cover a top surface of the insulation unit 5. Atop surface of the heat dissipation unit 6 opposite to the electrode wire 433 is free of coverage by a heat insulating material.

The heat dissipation unit 6 has a thickness that is not less than 3 μm. In certain embodiments, the heat dissipation unit 6 has a thickness that is not less than 10 μm. The cross-sectional area of the heat dissipation unit 6 can be increased by increasing the thickness thereof, thereby further improving the heat dissipation effect.

The heat dissipation unit 6 may be made of an electrically conductive and heat dissipating material, which may include metal and metal alloy that have good heat conduction and heat dissipation, such as gold, copper, silver, aluminum, and combinations thereof. The heat dissipation unit 6 may be formed as a single layer structure or a multi-layered structure via, e.g., a deposition process or an electroplating process.

The electrically conductive and heat dissipating material may further include a thermally conductive additive, such as aluminum oxide, aluminum nitride, or graphene.

It should be noted that, in this embodiment, the heat dissipation unit 6 simultaneously covers a plurality of the heterojunction bipolar transistors 3 which are arranged in an array. However, the heat dissipation unit 6 may only cover the emitter electrode 43 of one of the heterojunction bipolar transistors 3 to achieve the heat dissipation effect.

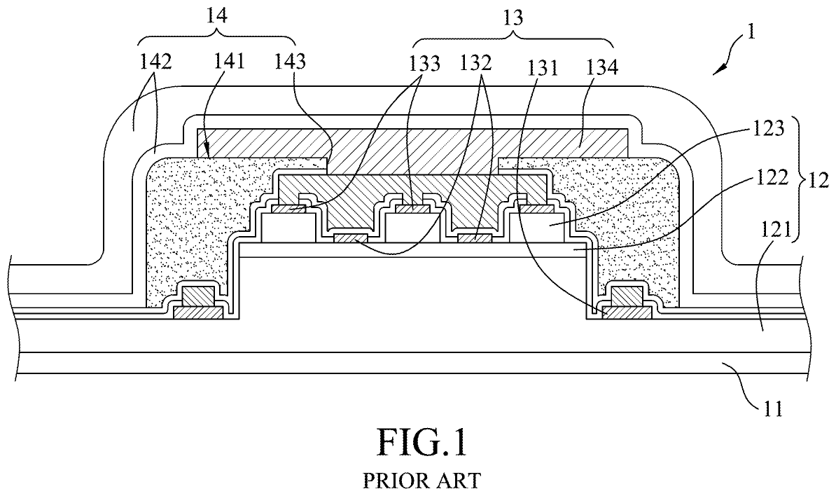

In summary, in comparison to the conventional heterojunction bipolar transistor 1 including the electrode wire 134 of the emitter electrode 133 being covered by the second insulating layer 142 (see FIG. 1), the semiconductor device of the present disclosure including the heterojunction bipolar transistor 3, which includes the exposed electrode wire 433 being covered by the heat dissipation unit 6 that has a thickness of not less than 3 μm and that has a relatively large heat dissipation area, is capable of effectively dissipating heat, so as to avoid the problem caused by using an insulating material having poor heat dissipation as employed in the conventional heterojunction bipolar transistor 1. In particular, when the semiconductor device of the present disclosure is a power amplifier including the heterojunction bipolar transistors 3 that are arranged in an array, the heat dissipation unit 6 can be directly disposed on and integrally connected to the heterojunction bipolar transistors 3, so as to more effectively improve the effect and uniformity of heat dissipation of the semiconductor device. Moreover, the thickness (i.e., height) of the heat dissipation unit 6 can be optimally adjusted to increase the cross-sectional area thereof, thereby further improving the overall heat dissipation effect of the semiconductor device of the present disclosure without affecting the package size thereof.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features specific details from one embodiment may be practiced together with one or more features or specific details from another embodiment, where appropriate, in the practice of the disclosure.

While the present disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A semiconductor device, comprising:
a substrate;
at least one heterojunction bipolar transistor including
a semiconductor unit including a collector layer, a base layer and an emitter layer that are sequentially formed on said substrate in such order, and
an electrode unit including a collector electrode, a base electrode and an emitter electrode that are respectively disposed on said collector layer, said base layer and said emitter layer, said emitter electrode including an electrode wire that extends in a direction away from said emitter layer;
an insulation unit covering said substrate and said heterojunction bipolar transistor such that said collector electrode, said base electrode and said emitter electrode are electrically isolated from one another, said insulation unit being formed with a plurality of openings respectively expose said collector electrode, said base electrode and said electrode wire of said emitter electrode; and
a heat dissipation unit covering said electrode wire of said emitter electrode and exposed outwardly, said heat dissipation unit being made of an electrically conductive and heat dissipating material, and having a thickness that is not less than 3 μm.

2. The semiconductor device as claimed in claim 1, wherein said semiconductor device comprises a plurality of said heterojunction bipolar transistors arranged in an array on said substrate, said heat dissipation unit covering and being connected to said electrode wire of each of said heterojunction bipolar transistors.

3. The semiconductor device as claimed in claim 2, wherein said heat dissipation unit extends through said openings, and covers a top surface of said insulation unit.

4. The semiconductor device as claimed in claim 1, wherein a top surface of said heat dissipation unit opposite to said electrode wire is free of coverage by a heat insulating material.

5. The semiconductor device as claimed in claim 1, wherein said semiconductor unit is made of a group III-V semiconductor material.

6. The semiconductor device as claimed in claim 1, wherein said collector electrode includes a collector metal layer, said base electrode includes a base metal layer, and said emitter electrode includes an emitter metal layer, said collector metal layer, said base metal layer and said emitter metal layer being respectively electrically connected to said collector layer, said base layer and said emitter layer, said electrode wire of said emitter electrode extending from said emitter metal layer.
